(19) United States
(12) Patent Application Publication
(10) Pub. No.: US 2007/0138583 A1
(43) Pub. Date: Jun. 21, 2007

(54) Nanoparticle Vibration and Acceleration Sensors

(75) Inventors: Eran Ofek, Bnei Brak (IL); Noel Axelrod, Bnei Brak (IL); Amir Lichtenstein, Bnei Brak (IL); Vered Pardo-Yissar, Bnei Brak (IL)

Correspondence Address: EDWARD S. SHERMAN, ESQ., 3554 ROUND BARN BLVD., SUITE 303, SANTA ROSA, CA, 95403, US

(73) Assignee: PHYSICAL LOGIC AG, Zug (CH)

(21) Appl. No.: 11/561,410

(22) Filed: Nov. 19, 2006

Related U.S. Application Data
(60) Provisional application No. 60/738,927, filed on Nov. 21, 2005.
(60) Provisional application No. 60/738,793, filed on Nov. 21, 2005.
(60) Provisional application No. 60/738,778, filed on Nov. 21, 2005.

(51) Int. Cl. H01L 29/84

(52) U.S. Cl. 257/417

(57) ABSTRACT

Nanoscale acceleration and vibration sensors comprise a thin beam attached to a first substrate, being generally suspended over the first substrate by a cantilevered attachment. The thin beam functions as a second substrate for a coating that has a resistivity that varies with strain in the beam. The coating comprises an ordered array of conductive nanoparticles coupled to the substrate either by a thin polymeric layer or a columnar spacer that is a molecular species. The polymer or columnar spacers preferably have a thickness that is at least two times the diameter of the conductive nanoparticles. A circuit to measure the resistance of the coating is formed on or with the beam substrate. The sensor may deploy an array of beam having different dimensions to represent a range of resonant frequencies that can be simultaneously detected and resolved. The sensor may deploy multiple beams of the same dimensions to provide redundancy in the case of partial device failure.

### CROSS REFERENCE TO RELATED APPLICATIONS

The present application claims priority to the U.S. provisional application having Ser. No. 60/738,927 entitled “Nanoparticle Vibration and Acceleration Sensors”, filed on Nov. 21, 2006 which is incorporated herein by reference. The present application also claims priority to the U.S. provisional application having Ser. No. 60/738,793 entitled “Nanoscale Sensor”, filed on Nov. 21, 2006 which is incorporated herein by reference. The present application further claims priority to the U.S. provisional application having Ser. No. 60/738,778 entitled “Polymer Nanosensor Device”, filed on Nov. 21, 2006 which is incorporated herein by reference.

### BACKGROUND OF INVENTION

The present invention relates to a sensor device for detecting small and nanoscale vibrations and accelerations.

The present invention relates to a composition of matter useful structures and configures therefore for forming sensors having an ultra-high sensitivity to acceleration, deformation, vibration and the like physical disturbances.

Prior methods of sensing small mechanical movements, vibration or acceleration generally deploy micro-electrical mechanical systems (MEMS) type devices. Such devices can be fabricated in part on silicon wafers extending technology developed for semiconductor microelectronic processing. The current generation of such sensors needs power, which increases their size and limits the life span. There is a continuing effort to increase the sensitivity of such devices, reduce their size and power consumption to expand their deployment to a wide range of engineering, industrial, aerospace and medical applications. It is particularly desirable to achieve a level of sensor miniaturization to be able to implantable such sensor devices into structures or operating equipment without disturbing operation or taking space.

Ideally, it would be desirable to have sensors that can detect motion on a molecular scale level, without interfering with molecular scale processes. For example, many biological processes occur on a cellular level and are inherently nanoscale. The failure of structures and engineering materials initiates as a nanoscale process.

It is therefore an objective of the present invention to provide sensor devices, capable of sensitivity in the detection of force, acceleration and vibration.

It is a further object of the present invention to provide such sensors that are capable of greater and nanoscale miniaturization than current devices.

It is still another objective of the present invention to provide such miniature, highly sensitive sensor devices that can be manufactured inexpensively a high yields.

### SUMMARY OF INVENTION

In order to detect the smallest movements or vibrations it would be desirable to deploy sensors having nano sized functional element that wherein the changes in the sensor properties would be readily measurable on a macroscopic level for high reliability and facile integration with electronic and instruments. For example, it would be desirable that the state of the sensor device could be read continuously by very low power electrical or optical measurements.

Such a nano sized sensor could conceivably be integrated with other items of manufacture or used in the human body yet without interfering with function. Indeed a nanoscale sensor element would have to be able to respond to affine deformation on a nanoscale to enable nanoscale devices.

Ideally, nanoscale sensor element that can be deposited by thin film deposition methods generally compatible with semiconductor type processing steps used to manufacture MEMS and nanoscale device.

The above an other advantages and objects have been accomplished by the invention of a nano-sensor that comprising a non-rigid substrate, a columnar spacer disposed on said non-rigid substrate, an array of particles bonded to said substrate via said spacer wherein at least one column is connected to each particle, whereby deformation of said non-rigid substrates results in a perturbation to the distribution of the nano-particles in said array to produce a measure change in the aggregate physical property of said array.

In still other and preferred embodiments of the invention, the columnar spacer is a molecular species bond to the substrate and the particles are nanospheres. The use of conductive nanospheres allows a relatively small perturbation to the array to be measured by electrical continuity across the device.

In other embodiments, conductive nanoparticles are disposed as an substantially ordered array by a polymeric spacer on a non-rigid substrate.

In additional embodiments of the invention the aforementioned nanosensor element are portion of a microelectromechanical (MEMS) system that deploys one or more cantilevered beams to detect acceleration and/or vibration. The cantilevered beams are in effect the substrate and hence by deform in response to acceleration and/or vibration thus disturbing the conductive nanoparticles disposed in the ordered array above the substrate. The disturbance of the conductive nanoparticles result in a measurable change in resistance between electrodes placed at on end of the beam.

The above and other objects, effects, features, and advantages of the present invention will become more apparent from the following description of the embodiments thereof taken in conjunction with the accompanying drawings.

### BRIEF DESCRIPTION OF DRAWINGS

FIG. 1 is a cross-section view schematically illustrating a first embodiment of a nano and molecular structure of the sensor (FIG. 1a) and the operative principles thereof (in FIG. 1b)

FIG. 2 is a cross-section view schematically illustrating a second embodiment of a nano and molecular structure of the sensor (FIG. 1a) and the operative principles thereof (in FIG. 1b)

FIG. 3 is a cross sectional view of one embodiment of implementing the nano and molecular structures of FIGS. 1 and 2 on a sensor device.

FIG. 4 is a plan view of the sensor device of FIG. 3.

FIG. 5 is a plan view of an alternate embodiment of a multi-sensor device.

### DETAILED DESCRIPTION

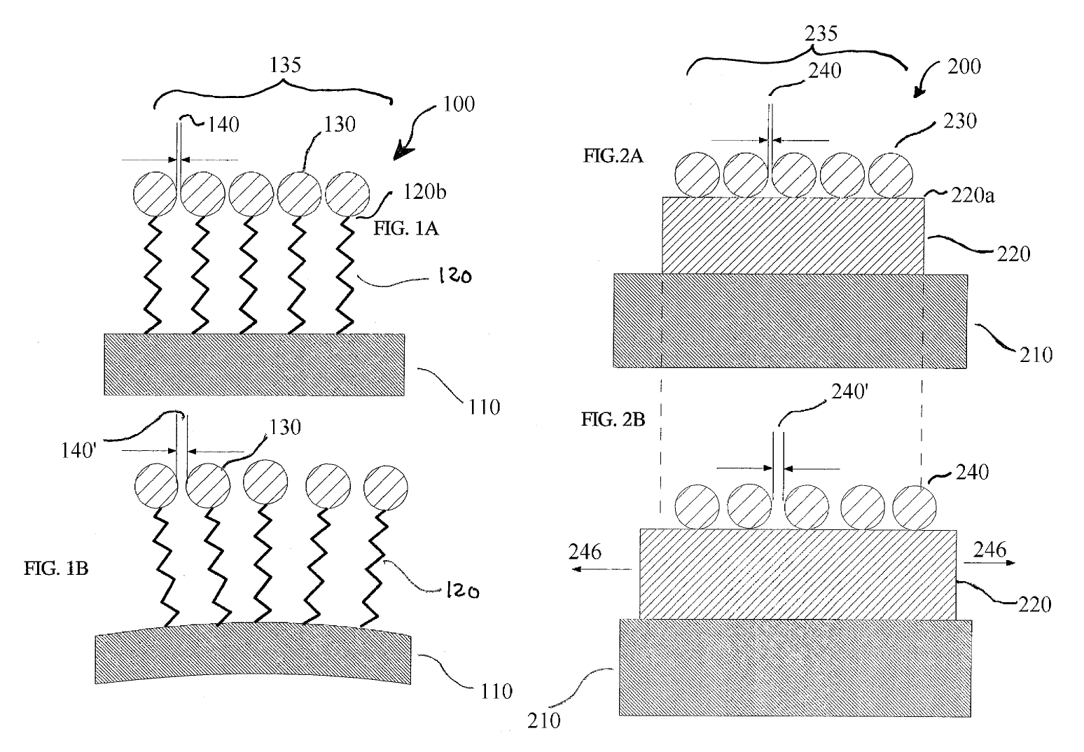

Referring to FIGS. 1 through 5, wherein like reference numerals refer to like components in the various views, there is illustrated therein a new and improved sensor layer, generally denominated 100 herein for use in sensor devices. Alternative forms of the sensor layer are generally denominated 200. Sensor devices that employ the sensor material designated 100 or 200 are generally denominated 300.

In accordance with the present invention, a nanoscale device 100 is constructed on a non-rigid substrate 110. As shown in FIG. 1A, various long chain molecules 120 or high aspect ratio molecular assemblies are attached at one end 120a to the non-rigid substrate to extend upward from the substrate to form a none electrically conductive column. One the other end of the column 120b is attached substantially equiaxed particles 130. The column distribution on the substrate is adjusted relative to the dimensions of the substrate to form a densely packed array of particle 135 such that the columns 120 act as spacers separating the particle 130 in the array 135 away from the substrate. Depending on the spacing and size of the molecular species that forms columns 120 and the size of the particles 130, a gap 140 may exist between particles 130 in array 135. The gap is preferably between about 0 to 0.5 nm, and more preferably 0 to 0.2 nm such that their will be electrical continuity across array 135 when particles 130 are conductive. It is believed that a gap of several nanometers between particles will still lead to electrical continuity because electrons can quantum mechanically tunnel across such a narrow gap. As the molecular species that form column 120 are selected to be relatively rigid, in at least one dimension, to transmit movement of the substrate to the particles, they also appear to sterically self-limit the density of attachment to the substrate, and hence the ultimate spacing of particle 130 to a greater uniformity.

FIG. 1B illustrates one operative principle of device 100 when non-rigid substrate 110 is slightly deformed, that is bent in the plane perpendicular to the drawing. The bending of substrate 110 is believed to cause a splay between columns 120 due to the change in curvature of the surface of substrate 110 due to bending. The splay between columns increases the separation between the columns at the upper end 120b, where they are attached to particle 130, such that the gap 140 shown in FIG. 1A now increase, which is shown in FIG. 1B as 140′. The increase in particle separation thus results in increase in resistance, decrease in electrical conductivity. As a very small increase in the gap between particles will result in a large increase in resistance, the ideal ordered array 135 provides a highly sensitive means to detect deformation of substrate 110.

In accordance with another aspect of the present invention, as illustrated in FIG. 2A, a nanoscale device 200 is constructed on a substrate 210. A relatively thin polymeric layer 220 is disposed on substrate 200. Substantially equiaxed particles 230 are attached on the upper or outer surface 220a of polymer layer 220. The particles 230 are deposited on polymer layer 120 to form an array 235 wherein the thickness of polymer layer 220 is of comparable size scale to the particles 230. In the case of conductive particles, their will be electrical continuity across array 235. A gap 240 may exist between particles 230 in array 235. It is believed that a gap of several nanometers between particles will still lead to electrical continuity because electrons can quantum mechanically tunnel across such a narrow gap. The gap 240 is preferably between about 0 to 0.5 nm, and more preferably 0 to 0.2 nm. As the particle spacing increases the probability of quantum tunneling decreases such that electrical resistance increases in a measurable fashion. Because the tunneling current is highly sensitive to distance variation when the array is closely packed, such a device is highly sensitive, and can undergo changes in resistance of four or more orders of magnitude when the particle separation increases by a mere fraction of the particle diameter. The structure in FIG. 2 is useful in sensor devices because the change in particle spacing can be measured either electrically, through continuity measurements across the array, or optically as will be further described with respect to other specific embodiments.

FIG. 2B illustrates the operative principle of the device when the polymeric layer 220 undergoes a disturbance, such as an affine deformation. When the polymeric layer 220 or substrate 210 is slightly deformed, either by strain in the direction of arrows 246, or bent in the plane perpendicular to the drawing, the particles 230 become spaced further apart, having a larger inter particle gap 240′. The increase in particle separation thus results in increase in resistance, decrease in electrical conductivity. As a very small increase in the gap 240 between particles 230 will result in a large increase in resistance, the ideal ordered array 235 provides a highly sensitive means to detect deformation of the polymeric layer 220 or the substrate 210.

The thickness of the polymer spacer is generally at least twice the diameter of the nanoparticles, or about 40 to 200 nm. Attachment of the nanoparticle to outer surface 220a of the polymer layer can be by covalent or ionic bonds. Examples of useful polymers for spacer 220 are both homopolymer and co-polymer, such as PDMS, PMMA, HEMA, cellulose, Azlactone polymers, polystyrene, polystyrene sulfonate, polydimethyl-diallyl-ammonium chloride (PDMDA), polyethylene imine, polyacrylic acid and polylysine. Polymers with azlactone functional groups are particularly desired because an azlactone group at the surface will readily react with available primary amines to produce a highly stable covalent bond. Such polymers include poly(2-vinyl-4,4-dimethylazlactone-co-acrylamide-co-ethylene dimethacrylate). Another preferred polymer spacer of layer 220 is polylysine as negatively charged nanoparticles can be bound to the surface 220a through electrostatic interactions with the pendent amine groups. The polylysine can be linear, branched, hyper branched, cross-linked or dendritic, so long as it can be readily deposited as a thin, smooth layer on an underlying substrate. A convenient form of polylysine is a 0.5% aqueous solution available from Sigma Chemical Company.

It should also be appreciated that with respect to the embodiments of FIG. 1 and FIG. 2 the term “substrate” may also encompass the underlying article or device to be measured. It should also be understood that the description of the substrate as non-rigid is only to the extent that the combination of modulus of elasticity and thickness do not inhibit either of the responses described with respect to FIG. 1 and FIG. 2. For example, a mineral or inorganic substrate like mica would have sufficient flexibility at a thickness of even 1-2 microns to function as a non-rigid substrate. It has also been found that polydimethylsiloxane (PDMS) with a thickness of 100 to 150 microns will be suitable as a substrate. Accordingly, depending on the substrate thickness alternative substrates include without limitation inorganic materials such as mica (nominally K2O.Al2O3.SiO2), silicon, silicon dioxide, glass and organic materials, or alternative organic polymers such as polydimethylsiloxane (PDMS), Polymethylmethacrylate (PMMA), polymers of Hydroxy ethyl methacrylate (HEMA) monomer, cellulose, azlactone polymers, polystyrene, and the like. It should also be appreciated the term substrate may also encompass the underlying article or device to be measured. In such instances, an initial substrate used in fabrication might be sacrificial or removed in the process.

In order to enable the operative principles discussed with respect to FIG. 1 and FIG. 2 the height of the molecular species, such as long chain molecules 120, that spaces the particles away from the substrate should be about two times the diameter of the particle 130. Likewise, with particular respect to FIG. 2, the thickness of the relatively thin polymeric layer 220 that spaces substantially equiaxed particles 230 away from substrate 200 should be at least about two times the thickness of the polymer layer 220, and preferably at least three or more times the thickness of polymer layer 220.

Preferred embodiments of the examples of FIG. 1 and FIG. 2 deploy particles 130 and 230 that are nano-scale, spherical and mono-disperse in size. More specifically the size of such nano-scale particle is preferably 1 to 100 nanometers. Further, the particles 130 and 230 are preferably conductive, and may include Au, Ag, Pt, Pd, phosphorus or boron-doped nickel (Ni(B) or Ni(Ph)), ITO, SnO2, and the like, as well as mixtures thereof. It being more preferable that the particles are of noble metals not subject to oxidation that would increase the inter-particle resistivity, i.e. Au, Pt or Pd.

Gold nanoparticles can be made by first dissolving 10 mg HAuCl₄ in 98 ml deionized water. While this solution is vigorously refluxing, with stirring or other agitation, 2 ml of a solution of 100 mg of trisodium citrate solution in 10 ml deionized water is rapidly injected to disperse uniformly. Continuing the reflux and stirring for about a 1 hour will produce a clear liquid with a red color. Thereafter, heating is stopped while stirring continues until the red liquid reaches room temperature.

As gold nanoparticles functionalized with a single reactive group are commercially available, they can be readily attached to any of the columnar species or thin polymer layer described herein having a complimentary, that is co-reactive group on the outer surface. For example, Mono-Sulfo-NHS-“NANOGOLD”™ is a 1.4 nm gold nanoparticle with a single reactive group, a sulfo-N-hydroxysuccinimide ester (sulfo-NHS) that reacts with primary amines under mild conditions (circa pH 7.5 to 8.2) (Available from Nanoprobes, Incorporated: 95 Horse Block Road, Yaphank, N.Y. 11980-9710, USA). An array of Mono-Sulfo-NHS-“NANOGOLD”™ particles are readily attached to any amine terminated columnar spacer by incubation of the substrate with the Mono-Sulfo-NHS-“NANOGOLD”™ for 2 hours at room temperature. The substrate is then washed and dried to remove excess “NANOGOLD”™ reagent.

It should be appreciated that alternative ways of depositing the columnar spacers includes bonding a non-conductive columnar spacer produced by self-assembled monolayer (SAM) to the substrate. Such a SAM may consist substantially of —(—CH2-)-, liquid crystal molecules and the like. Further details on these and other methods of binding micro and nano sized metallic particles to substrates are disclosed in U.S. Pat. No. 6,242,264 (to Natan, et al., issued Jun. 5, 2001 for “Self-assembled metal colloid monolayers having size and density gradients”), which is incorporated herein by reference.

In alternative embodiments, the particle or preferred nanoparticles need not be covalently bound to the column or the thin polymer layer. For example, nanoparticles may also be attached to the non-conductive spacer by ionic bonding. For example, an amine group on the top of the column and a citrate functionalized nanoparticle. Alternatively, depending on the threshold of force measurement desired, it is possible use larger particles and form the columnar structure by lithographically etching or molding spacer having micro or possibly nano-dimensions. In such cases, it is possible that the substrate and spacer layer, the collection of columns 120 are formed out of a single monolith, rather than a layered material.

When the initially deposited nanoparticles have a diameter substantially less than the diameter of the columnar molecule that acts as a spacer, it is desirable in an additional step to grow the nanoparticles of gold. It is also desirable to grow or enlarge the as deposited nanoparticles when the columnar molecules have a spacing that is substantially larger than the nanoparticles diameter. It is also desirable to grow the initially deposited conductive nanoparticle when they are not deposited on the thin polymer layer at a insufficient density to form a conductive array. In a preferred embodiment, the initially deposited conductive nanoparticles have a diameter of about 1.4 nm, after which the diameter is preferable grown to about 20 to 100 nm, depending on the initial particle spacing.

Methods of growing conductive metal particle bound to surface are well known in the field of histology, wherein various reagents are commercially available to cover nanospheres of gold with silver, gold or silver followed by a thin gold coating. For example the “GoldEnhance”™ reagent kit is also available from Nanoprobes for this purpose. Alternatively, nanoparticles of gold can be expanded by incubation at room temperature on an aqueous solution of 0.5 mM HAuCl₄ and 0.5 mM NH₂OH for about 2 minutes. The substrate is then washed with water and blown dry with Nitrogen or another inert gas. The gold particles are grown to the desired size by simply extending the incubation period in the Gold Enhance reagent for as long as is desired.

It should be understood that the desired final size of the conductive nanoparticle is that which sufficiently reduces the interparticle gap to provide the intended device sensitivity and dynamic range. Although it is possible to use repeated electrical continuity measurements to determine when the conductive particles have grown to the point at which they touch, a preferred method utilizes the change in color from blue, for the original NANOGOLD particles, to red as the particles grow to a size where they touch, and no longer interest with incident light as quantum dots. The change in color occurs because the surface plasmon resonance absorption of discrete gold nanoparticles red shifts with a broader spectral shape from the initial spectral placement (centered at roughly 545 nanometers) as the particles move farther apart. Accordingly, in the more preferred embodiments it is preferable that the substrate 110, or the combination of substrate and spacer, are somewhat reflective so this red shift can be observed visually or measured in reflection from the substrate to terminate the growth of the nanoparticles of gold. In the case of this example, it was preferable to grow the gold-nanoparticles to a diameter of about 20 nm. However, in other embodiments depending on the width, length, binding density and flexibility of the molecular species that constitutes of column 120 a different range of final particle size might be preferred. As a generally preferred range of the size of particle 120 is 15 to 40 nm, the height of the columns is generally at least twice this value, or about 30 to 80 nm.

In light of the foregoing, one of ordinary skill in the art will appreciates that alternative nano scale particles include non-conductive particles having a metallic or otherwise stable conductive coating, such as phosphorus or boron-doped nickel that might be deposited by electro less deposition from solution.

It should be appreciated that the particle arrays of the instant invention can be distinguished from prior art sensors or devices that measure changes of resistivity of dispersed conductive particles. Such dispersions are not controlled, that is they are random and hence depend on the density of particles reaching a percolation threshold to function. However, when the percolation threshold is reached their will also be a random separation distance between particles through the material.

However, scale, size and structure of the arrays of the instant invention offers unique advantages over this prior art. First, it should be appreciated that because the spacing between particles can be controlled by the molecular structure of the species forming the column, the device sensitivity can be extremely high (that is detect nanoscale deformation) with a very high dynamic range. This can be understood from the relationship between the resistance, R, between adjacent particles when the conduction mechanism is tunneling which can be calculated as:
R=(8πhs/3a²γe²)exp(γs)

wherein h is Plank's constant, s is the distance between particles, a² is the effective cross-sectional area and γ is calculated from fundamental constants (wherein m is the electron mass) and the height of the potential barrier is φ as
γ=4π(2mφ)^{0.5}h

Accordingly, a small increase in particle spacing, s, leads to a more than exponential increase in resistance, R. Hence, by selection of the device dimension through the construction with uniform precursors, i.e. the columns 120 and the particle 130, a device can be constructed wherein the slightest perturbation to the dense array of particles will initiate a large change in resistance. Further, since the array is spatially uniform it can be decreased in size to the minimum number of particle necessary to make ohmic contact with external junctions.

However, a dispersed particle array cannot be subdivided to such an extent because as the scale of division approaches the percolation scale their will be massive variations in the particle density and spacing, hence giving wide fluctuations in the base resistance and the dynamic range of each such portion. For the same reasons local deformations of such prior art materials smaller that the percolation scale cannot be reliability measured.

In contrast, the sensor device of the instant invention can be reduced on a lateral scale commensurate with the event or object to be measured, as same local deformation of the substrate will produce the same response regardless of the lateral position in the area. Finally, as the nano-sensor has molecular dimensions it can be expected to be responsive to and detect molecular motion on a comparable scale that is just above phonon vibrations. Further, the homogenous nature of the conductive particle array ensures ohmic contact with external electrodes, which can be problematic when conductive particles are dispersed in an insulating matrix, as the matrix can form an outer layer of the device.

However, a dispersed particle array cannot be subdivided to such an extent because as the scale of division approaches the percolation scale their will be massive variations in the particle density and spacing, hence giving wide fluctuations in the base resistance and the dynamic range of each such portion. For the same reasons local deformations of such prior art materials smaller that the percolation scale cannot be reliability measured.

In contrast, the sensor device of the instant invention can be reduced on a lateral scale commensurate with the event or object to be measured, as same local deformation of the substrate will produce the same response regardless of the lateral position in the array. Finally, as the nano-sensor has molecular dimensions it can be expected to be responsive to and detect molecular motion on a comparable scale, which is just above phonon vibrations. Further, the homogenous nature of the conductive particle array ensures ohmic contact with external electrodes, which can be problematic when conductive particles are dispersed in an insulating matrix, as the matrix can form an outer layer of the device.

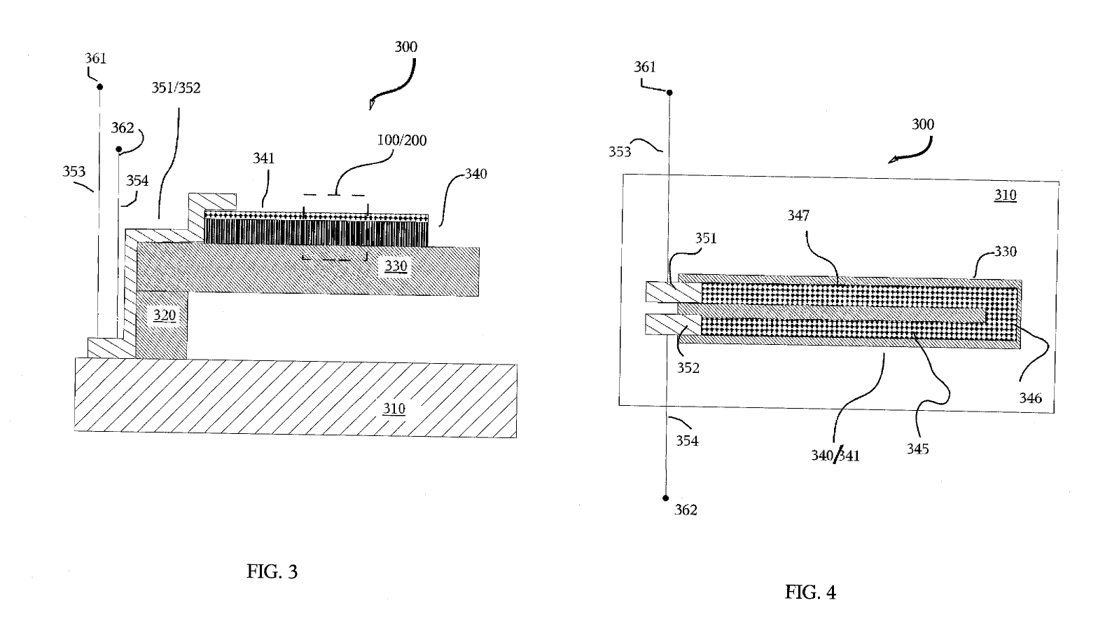

FIG. 3 illustrates a sensor device 300 in cross sectional elevation that utilizes the sensor material 100 or 200 shown in FIGS. 1 and 2 respectively. FIG. 4 illustrates sensor device 300 in plan view. The sensor 300 comprises a substrate 310 and a supporting plate 320 extending upward from the substrate 300. A beam 330 is coupled on at least one end to the supporting plate 320 so as to extend over the substrate 310. A strain sensitive coating conductive coating 340 is disposed on at least one surface of the beam 330. Thus, the portion of the beam 330 and coating 340 encircled by the dashed lines is now labeled 100 or 200 to indicate that it may correspond substantially to the embodiments described with respect to FIGS. 1 and 2, as well as equivalents thereof. Such equivalents are fully disclosed in Appendix 1 and 2, attached hereto and incorporated herein by reference, being copies of co-pending non-provisional patent applications for a “Nanoscale Sensor” (filed Nov. 16, 2006 under docket # 173.01NP and having Ser. No. 11/560,826) and for “Polymer Nanosensor Device (filed on Nov. 19, 2006 under docket # 173.02NP and having Ser. No. 11/561,405).

As is more apparent in the plan view of FIG. 4, a pair of electrodes 351 and 352 are disposed in electrical contact to the conductive upper layer 341 of strain sensitive coating 340. The strain sensitive coating 340 is arranged in a U-shaped circuit having sub-portions 345, 346 and 347. The sub-portion extend proximally from the portion of beam 330 overlaying or adjacent plate 320. Sub-portion 245 extends from electrode 352 to about the end of beam 340, connecting to sub-portion 346. Sub-portion 347 extends from its connection with sub-portion 346 along the length of beam 330 making contact with the second electrode 351. Each of the electrodes 351 and 352 are preferably connected by conductive traces 353 and 354 respectively to external electrical contacts 361 and 362. The external contact may be used to connect external signal processing and amplification circuitry known in the art. It is preferable connections to signal processing and amplification circuitry are made on substrate 310, it being more economical to integrate the sensor element 300 on the common substrate 310 with integrate circuits associated with amplification and digital signal processing. The amplification and digital signal processing circuit measure a change in resistance there between in response to the deformation of the portion of said beam that extends over said substrate.

The instant invention differs from prior art MEMS type sensors in several import aspects. Although the general cantilever geometry shown in FIGS. 3 and 4 is well known in the art, the inventive method of detecting the movement of the cantilever beam disclosed herein offers significant advantages. Prior art methods of detecting the movement of the cantilever are either capacitive or piezoelectric. Capacitive detection requires fabricating electrodes both under the tip of the beam and the adjacent area of the substrate. Capacitive devices are known to fail when the electrodes surface stick to each other. In contrast, it should be apparent that in the instant invention the supporting plate 320 can be arbitrarily height to eliminate the possibility that the end of beam 330 could reach substrate 310.

Piezoelectric detection requires placing a pair of opposing electrodes on the portion of the beam that undergoes deformation. The beam itself must be a piezoelectric material. Further, the placement of electrodes in the capacitive and piezoelectric detection methods requires more complex manufacturing steps than the instant invention. In the instant invention the electrodes 351 and 352 need not be on the beams itself, but can be disposed solely on the substrate 310 and/or the supporting plate 320 by simply extending the placement of the strain sensitive coating 340 past the portion of the beam that undergoes deformation. As the electrode itself need not deform with the beam, the beam size can be much smaller, and hence more sensitive to lower amplitude vibrations or to detect and discriminate a much lower magnitudes of inertial forces. Further as the strain sensitive coating 340 has a greater effective strain resistance coefficient than piezoelectric materials used to form beam 330, the dynamic range of the device 300 is much larger.

It should be appreciated that the strain sensitive coating 340 can be patterned in a U or other shape by numerous methods known in the art of microfabrication. One such method is to first coat the device with a continuous layer of strain sensitive coating 340 (or just the thin polymer film or columnar spacer) and removing the undesired portion via masking and ablation, as is commonplace in semiconductor device fabrication. In an alternative method, a coupling agent for the columnar spacer (or the thin polymer spacer layer) can be deposited directly in the U-shaped circuit by molecular imprinting. As a non-limiting example, suitable methods of molecular imprinting are taught in U.S. Pat. No. 6,251,280 (issued to Dai, et al. Jun. 26, 2001), which is incorporated herein by reference. It should be further appreciated that as the columnar spacer or thin polymer layer that separates the conductive particles from the substrate is non-conductive, a conductive beam, when suitably masked on selected portions, can serve as one electrode in the circuit itself.

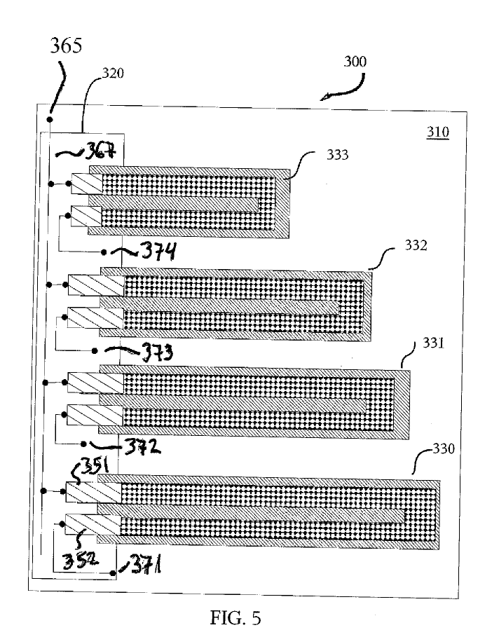

FIG. 5 is another alternative embodiment of the invention in which a single substrate 310 comprises a plurality of beam having sensor coating 340. Each beam is connected to a common electrode 365 via a bus 367. Each of beams 330, 331, 332 and 332 has disposed on its upper surface the strain sensitive coating 340 as a U-shaped circuit. Thus, each U-shaped circuit is at one connected via electrode 351 to bus 367 at one end. The other end of each U-shaped circuit is connected to electrode 352. Electrode 352 on each beam is connected to a separate electrical contact for measuring the change in resistance across the U-shaped circuit formed by strain sensitive coating 340. Thus, the time dependent resistance of the coating 340 on beam 330 between terminals 365 and 371 is expected to vary with the resonant frequency characteristic of beam 330 when the sensor is suitably excited by an external vibration source. Likewise the time dependent resistance of the coating on beam 331 is measured before terminal 365 and 372, and likewise for beam 332 (terminals 365 and 372) and beam 333 (terminal 365 and 372).

The multiple beams 330, 331, 332 and 332 are different sizes so that selected beams deflect at their particular resonant frequency when the device is excited or energized by a vibration having frequency components that match the self-resonance frequency of the beams in the array. The use of multiple cantilever beams in a vibration wave detection device is disclosed in U.S. Pat. No. 6,079,274 (to Ando et al., issued Jun. 27, 2000).

It is preferable that the device deploys selected beams of the same of resonant frequency for redundancy should some of the beams or circuit fail, as described in U.S. Pat. No. 6,750,775 (to Chan et al, issued Jun. 15, 2005), which is incorporated herein by reference.

While the invention has been described in connection with a preferred embodiment, it is not intended to limit the scope of the invention to the particular form set forth, but on the contrary, it is intended to cover such alternatives, modifications, and equivalents as may be within the spirit and scope of the invention as defined by the appended claims.

1. A sensor comprising:
a) a substrate
b) a supporting plate extending upward from said substrate
c) a beam coupled on at least one end to said supporting plate and extending over said substrate,
d) a strain sensitive conductive coating disposed on at least one surface of said beam that extends over said substrate,
e) a pair of electrodes disposed in electrical contact to said strain sensitive coating to measure a change in resistance there between in response to the deformation of the portion of said beam that extends over said substrate.
f) wherein said strain sensitive coating comprises a 2-dimensional array of substantially mono-disperse conductive nanoparticles mechanically coupled to said beam wherein the nanoparticles in said array separate from each other in response to the deformation of said beam.

2. A sensor according to claim 1 wherein the nanoparticles in the 2-dimensional array are coupled to said beam by at least one intervening thin polymer layer.

3. A sensor according to claim 2 wherein the intervening thin polymer layer has a thickness of at least twice the diameter of the nanoparticles.

4. A sensor according to claim 1 wherein the nanoparticles in the 2-dimensional array are coupled to said beam by a non-conductive columnar spacer disposed on said beam.

5. A sensor according to claim 4 wherein the non-conductive columnar spacer has a height that is at least twice the diameter of the nanoparticles.

6. A sensor according to claim 1 wherein the strain sensitive coating extends to a selected portion of the sensor device that does not bend, making electrical contact with at least one of said electrodes on said selected portion.

7. A sensor according to claim 1 wherein the nanoparticles are selected from the group consisting of Au, Ag, Pt, Pd, Ni(B) or Ni(Ph), ITO, SnO2.

8. A sensor according to claim 7 wherein the particle are gold nanoparticles

9. A sensor according to claim 2 wherein the polymer spacer has a thickness that is at least about two times the diameter of the nanoparticles.

10. A sensor according to claim 2 wherein the polymer spacer comprises two or more layer of different polymers.

11. A sensor according to claim 10 wherein at least one of the polymer layers is a charged polymer.

12. A sensor according to claim 4 wherein the nanoparticles in the array have an initial gap before separation that is between about 0 to 2 nm.

13. A sensor according to claim 12 wherein the gap between the nanoparticles in the array have an initial gap before separation that is between about 0.2 to 0.7 nm.

14. A sensor comprising:
a) a substrate,
b) at least one supporting plate extending upward form said substrate,
c) tow or more beams coupled on at least one end to said supporting plate and extending over said substrate, wherein each beam further comprises:
i) a strain sensitive conductive coating disposed on at least one surface of said beam that extends over said substrate,
ii) a pair of electrodes disposed in electrical contact to said strain sensitive coating to measure a change in resistance there between in response to the deformation of the portion of said beam that extends over said substrate,
iii) wherein said strain sensitive coating comprises a 2-dimensional array of substantially mono-disperse conductive nanoparticles mechanically coupled to said beam wherein the nanoparticles in said array separate from each other in response to the deformation of said beam.

15. A sensor according to claim 9 wherein each of said two or more beam has a different characteristic resonant frequency.

16. A sensor according to claim 9 wherein each of said two or more beam has a different lengths.

17. A sensor according to claim 9 wherein at least two of said two or more beam have the same physical dimensions.

18. A sensor according to claim 9 wherein the nanoparticles are selected from the group consisting of Au, Ag, Pt, Pd, Ni(B) or Ni(Ph), ITO, SnO2.

19. A sensor according to claim 9 wherein the gap between the nanoparticles in the array have an initial gap before separation that is between about 0 to 2 nm

20. A sensor according to claim 19 wherein the gap between the nanoparticles in the array have an initial gap before separation that is between about 0.2 to 0.7 nm.
